(19) United States
(12) Patent Application Publication
(10) Pub. No.: US 2021/0202350 A1
(43) Pub. Date: Jul. 1, 2021

(54) METHOD FOR PRODUCING A HEAT-SPREADING PLATE, HEAT-SPREADING PLATE, METHOD FOR PRODUCING A SEMICONDUCTOR MODULE AND SEMICONDUCTOR MODULE

(71) Applicant: Heraeus Deutschland GmbH & Co. KG, Hanau (DE)

(72) Inventor: Ronald EISELE, Surendorf (DE)

(73) Assignee: Heraeus Deutschland GmbH & Co. KG, Hanau (DE)

(21) Appl. No.: 15/999,536

(22) PCT Filed: Feb. 9, 2017
(86) PCT No.: PCT/EP2017/052862

§ 371 Date: Aug. 20, 2018

(30) Foreign Application Priority Data
Feb. 19, 2016 (EP) 16156488.5

(51) Int. Cl. H01L 23/373; H01L 23/367; H01L 21/48; H01L 23/00; B23K 20/02; B32B 15/01

(52) U.S. Cl. CPC H01L 23/3735; B23K 2103/02; H01L 21/4882; H01L 23/3736; H01L 24/32; B23K 20/026; B32B 15/015; H01L 2224/32225; H01L 2224/48091; H01L 2224/48227; H01L 2224/73265; H01L 24/73; H01L 24/48; H01L 2924/19107; H01L 23/3672

(57) ABSTRACT

One aspect relates to a method for producing a heat-spreading plate for a circuit carrier. At least one first layer made of a first material having a first coefficient of expansion and at least one second layer made of a second, low-stretch material having a second coefficient of expansion that is smaller than the first coefficient of expansion are bonded to each other at a bonding temperature of 150° C.-300° C. by means of a low-temperature sintering process. At least one bonding layer from a bonding material is formed between the first layer and the second layer and the bonding temperature essentially corresponding to the mounting temperature at which the produced heat spreading plate is connected to at least one circuit carrier.

The invention relates to a method for producing a heat-spreading plate for a circuit carrier. Further, the invention relates to a heat-spreading plate. Moreover the invention relates to a method for producing a semiconductor module as well as to a semiconductor module.

Conductor tracks and heat-spreading plates in power electronic superstructures normally consist of copper. Copper has good current and heat conducting properties. Moreover this is a very cheap material. Silver has even better current and heat conducting properties, but is several times more expensive than copper. The use of silver for achieving the required thicknesses of 0.2-2.0 mm for conductor tracks or of 1.5-5 mm for heat-spreading plates would be unacceptably expensive. Power semiconductors typically consist of silicon, silicon carbide or gallium nitride. Materials of power semiconductors and materials of ceramic circuit carriers exhibit a distinctly lower thermal expansion coefficient than copper. Copper has an expansion coefficient of 17.8 ppm/K, whereas typical ceramic circuit carriers have thermal expansion coefficients of 2.5-7.1 ppm/K.

Copper alloys and copper platings comprising low-stretch metals have already been used in an effort to reduce the thermal expansion of copper conductor tracks and copper heat-spreading plates. There exist, for example, copper tungsten alloys (CuW) and copper molybdenum alloys (CuMo). Cu—Mo—Cu platings are also known. The resulting thermal expansions lie between 8 ppm and 12 ppm/K.

From a technological point of view CuW and CuMo alloys as well as Cu—Mo—Cu alloys are difficult to produce and extremely expensive. In particular, in view of the large melting point difference between copper and the alloy constituents of tungsten (W) and molybdenum (Mo), producing an alloy requires extremely comprehensive method steps until a successful alloy is obtained. Moreover the heat conductivity of pure copper is greatly reduced by the production of the alloy. This represents a substantial disadvantage for the cost-intensive alloy.

The plating of copper and molybdenum has to be carried out at very high temperatures of e.g. 600° C.-800° C. in order to support the compound-forming diffusion. During this high-temperature process it is important to prevent the destructive oxidation of the copper material, requiring cost-intensive measures.

A further disadvantage of the diffusion-annealed layer—sequence lies in the strong deformation and distortion occurring after cooling from the diffusion temperature down to the ambient temperature/operating temperature of the power-electronic assembly, which is connected to the heat-spreading plate. In order to produce planar heat-spreading plates, these have to be stretch-rolled in roller sets. This leads to a partially mechanical destruction of the diffusion layer. An asymmetrically layered sequence of copper layers and molybdenum layers using diffusion-annealing, is therefore not realisable.

Based on this state of the art it is the objective of the present invention to propose a method for producing a heat-spreading plate, which is extremely easy and cost-effective to carry out and with the aid of which an optimised heat-spreading plate can be produced.

Further it is an objective of the invention to propose a heat-spreading plate, which is extremely low-stretch and at the same time cost-effective. Further, it shall be possible with the aid of the heat-spreading plate according to the invention to achieve a small but controllable overall deformation of the heat-spreading plate.

Further it is an objective of the present invention to propose a method for producing a semiconductor module. Further it is the objective of the present invention to propose a further developed semiconductor module, wherein the semiconductor module is extremely low-stretch permitting a low but controllable overall deformation of the heat-spreading plate together with a connected circuit carrier.

According to the invention the objective is achieved by the subject of claim 1 as regards the method for producing a heat-spreading plate, by the subject of claim 6 as regards the heat-spreading plate for a circuit carrier, by the subject of claim 15 as regards the method for producing a semiconductor module comprising a heat-spreading plate and at least one circuit carrier, and by the subject of claim 18 as regards the semiconductor module comprising a heat-spreading plate and at least one circuit carrier.

The invention is based on the idea to propose a method for producing a heat-spreading plate for a circuit carrier, wherein at least one first layer made of a first material with a first expansion coefficient and at least one second layer made of a second low-stretch material with a second expansion coefficient smaller than the first expansion coefficient are bonded to each other at a bonding temperature between 150° C. and 300° C. Especially preferably a low-temperature sintering process is used for bonding the first layer made of a first material to the second layer made of a second material.

According to the invention at least one first bonding layer made of a bonding material is formed between the first layer and the second layer.

The bonding temperature substantially corresponds to a mounting temperature when connecting the produced heat-spreading plate to at least one circuit carrier.

In one embodiment of the method according to the invention the bonding temperature may 200° C.-280° C., in particular 220° C.-270° C., in particular 240° C.-260° C., in particular 250° C.

The bonding material of the bonding layer can preferably produce a bond which withstands temperatures above the bonding temperature. Preferably the bonding material comprises a diffusion material, in particular silver (Ag) and/or a silver alloy and/or gold (Au) and/or a gold alloy and/or copper (Cu) and/or a copper alloy.

The first material having the first expansion coefficient of the at least first layer preferably comprises copper and/or a copper alloy.

The second low-stretch material having the second expansion coefficient of the at least second layer preferably comprises a nickel alloy, in particular Invar (Fe₆₅Ni₃₅) or Invar 36 (Fe₆₄Ni₃₆) or Kovar (Fe₅₄Ni₂₉Co₁₇) and/or tungsten (W) and/or an iron-nickel-cobalt alloy (FeNiCo alloy). A particularly preferred material as regards the second material of the at least second layer has proven to be molybdenum (Mo) or a molybdenum alloy.

In principle the second material used can be any metal which has an expansion coefficient lower than the metal of the first material. Insofar as the first material is copper or a copper alloy, or insofar as the first layer consists of copper or a copper alloy, all metals having an expansion coefficient lower than copper are suitable as the second material.

The lower the expansion coefficient of the second material and the higher at the same time the heat conductivity of the second material, the more this material is suitable to be used as second material. The electric conductivity is physically connected to the thermal conductivity. Therefore all metals having good thermal and/or electric conductivity as well as low thermal expansion are well suited for use as the second material or for use in the second material.

The table hereunder shows, in column 6, the expansion coefficient of the material named in column 1. Thus all materials having an expansion coefficient lower than copper are suitable to serve as second material/are used as the second material.

1) material (symbol)
2) density
3) elasticity modulus
4) melting temperature
5) heat conductivity
6) expansion coefficient linear (10⁺⁶*alfa)
7) specific heat
8) electrical conductivity
9) temperature coefficient of electric resistance (10⁺³*alfa)

| | | | | | | | | |
|---|---|---|---|---|---|---|---|---|
| 1) material | 2) density | 3) e. m. | 4) temp. | 5) h. c. | 6) exp. | 7) sp. | 8) electr. | 9) temp. |
| | | | | | coeff. | heat | conduct. | coeff. |

| | | | 4) Temp. | | | | | |
|---|---|---|---|---|---|---|---|---|
| | 2) Dichte | 3) E. M. | Grd | 5) WLF | 6) Ausd. k. | 7) sp. W | 8) El. Leitf. | 9) Temp. K |
| 1) Werkstoff | kg/dm³ | kp/mm² | Celsius | cal/cmsecgrd | m/mgrd | cal/grgrd | m/Ohmmm² | l/grd |
| Silber | 10.49 | 8160 | 960 | 1.00 | 19.7 | 0.056 | 63 | 4.10 |
| Kupfer | 8.96 | 12500 | 1083 | 0.94 | 16.2 | 0.092 | 60 | 4.31 |
| Eisen | 7.87 | 21550 | 1530 | 0.18 | 11.7 | 0.11 | 10.3 | 6.57 |
| Grauguß | 7.20 | 8000-13000 | 1150-1300 | 0.13 | 9.0 | 0.13 | 1-2 | |
| Molybdän | 10.2 | 33630 | 2625 | 0.35 | 5 | 0.061 | 19.4 | 4.73 |
| Monelmetall | 8.58 | 15900 | 1320-1350 | 0.06 | 14 | 0.12 | 1.6 | 0.19 |
| Nickel | 8.90 | 19700 | 1455 | 0.22 | 13.3 | 0.105 | 14.6 | 6.75 |
| Niob | 8.57 | 16000 | 2415 | | 7.0 | 0.0065 | 7.7 | |
| Osmium | 22.5 | 57000 | 2700 | | 4.6 | 0.031 | 10.4 | 4.45 |
| Platin | 21.45 | 17320 | 1774 | 0.17 | 8.9 | 0.032 | 10.2 | 3.92 |
| Stahl C 15 | 7.85 | 20800 | 1510 | 0.12 | 11.1 | 0.11 | 9.3 | 5.7 |
| Stahl C 35 | 7.84 | 20600 | 1490 | 0.12 | 11.1 | 0.11 | 8.6 | 5.2 |
| Stahl C 60 | 7.83 | 20400 | 1470 | 0.11 | 11.1 | 0.11 | 7.9 | 4.7 |
| 41Cr4 | 7.84 | 20700 | 1490 | 0.1 | 11.0 | 0.11 | 8.0 | |
| X10Cr13 | 7.75 | 22000 | 1500 | 0.065 | 10.0 | 0.11 | 1.7 | |
| 36% Ni- | 8.13 | 14500 | 1450 | 0.025 | 0.9 | 0.123 | | |
| Stahl | | | | | | | | |
| Tantal | 16.6 | 18820 | 3000 | 0.13 | 6.6 | 0.036 | 8.1 | 3.47 |
| Titan | 4.54 | 10520 | 1800 | 0.041 | 10.8 | 0.126 | 1.25 | 5.46 |
| Vanadium | 6.0 | 15000 | 1735 | | 8.5 | 0.12 | 3.84 | |
| Wismut | 9.8 | 3480 | 271 | 0.020 | 12.4 | 0.034 | 0.94 | 4.45 |
| Wolfram | 19.3 | 41530 | 3380 | 0.48 | 4.5 | 0.032 | 18.2 | 4.82 |
| Zirkon | 6.5 | 6970 | 1850 | | 10 | 0.066 | 2.44 | 4.4 |

Re: English translation of metals from the table above:

Silver, copper, iron, grey cast iron, molybdenum, Monel metal, nickel, niobium, osmium, platinum, steel C15, steel C35, steel C60, 41Cr4, X10Cr13, 36% Ni-steel, tantalum, titanium, vanadium, bismuth, tungsten, zirconium

Bonding of the at least first layer to the at least second layer and to the bonding layer may be effected by means of pressure application, in particular at a pressure of 5 MPa-30 MPa, in particular 10 MPa-28 MPa, in particular 25 MPa.

Low-temperature sintering for bonding the at least first and at least second layers and the at least one bonding layer is preferably effected at temperatures between 150° C. and 300° C. and at an applied pressure of 5 MPa-30 MPa. Especially preferably low-temperature sintering is effected at a temperature of 250° C. and a pressure of 25 MPa, wherein sintering is preferably carried out for a duration of 1 to 10 min, e.g. 4 min.

With the method for producing a heat-spreading plate the bonding temperature essentially corresponds to the mounting temperature when connecting the produced heat-spreading plate to at least one circuit carrier. The bonding temperature may correspond exactly to the mounting temperature. Furthermore it is possible for the bonding temperature to deviate from the mounting temperature by max. 20%, in particular max. 15%, in particular max. 10%, in particular max. 5%. Calculation of the percentage deviation of the bonding temperature from the mounting temperature is effected on the basis of a calculation of the difference between the bonding temperature in Kelvin and the mounting temperature in Kelvin.

Apart from performing low-temperature sintering it is also possible to bond individual layers of the heat-spreading plate to each other by diffusion soldering, wherein high-melting-point point intermetallic phases are formed. Another possibility is to use adhesives for bonding individual layers of the heat-spreading plate to each other.

Preferably the bonding material is applied as sintering material or a constituent of the sintering material between the at least first layer and the at least second layer. A compound capable of sintering a conductive layer can thus be used to form a sintered bond between the two layers to be bonded. The compound still capable of sintering may be applied in the form of an ink, a paste or sinter preform in the form of a layered pressed part. Sinter preforms are created through the application and drying of metal pastes/metal sintering pastes. Such sinter preforms are still capable of being sintered. Alternatively it is possible for the bonding material to be formed as a foil, in particular a metal foil and for this foil, in particular metal foil, to be arranged between the first layer and the second layer.

It is possible for the sintering paste which comprises the bonding material/consists of the bonding material, to be applied by printing, in particular screen printing or stencil printing, to the first layer and/or the second layer. Optionally the sintering paste/metal sintering paste can be dried prior to performing the sintering process as such. Without passing through the liquid state, the metal particles of the sintering paste bond to each other during sintering by diffusion, forming a firm metallic bond/metal bond between the at least first and second layers, which is both electric-current conducting and heat-conducting. Especially preferably bonding of the at least first and second layers is effected using a sintering paste which comprises silver and/or a silver alloy and/or silver carbonate and/or silver oxide.

With a further embodiment of the invention it is possible, prior to applying a bonding layer, to apply to the first and/or second layer, preferably to the second layer, a layer applied e.g. by electroplating or sputtering, which serves to enhance the adhesion of the bonding layer/the sealing layer. Insofar as the second layer is a molybdenum layer/comprises molybdenum, a nickel-silver layer (NiAg layer) can be applied by way of electroplating to the side of the second layer which is to be bonded. The bonding material, in particular silver, is able to adhere especially well to this nickel-silver layer.

Further the invention is based on the idea to propose a heat-spreading plate for a circuit carrier, wherein the heat-spreading plate is preferably produced using a previously mentioned method according to the invention.

The heat-spreading plate according to invention comprises:
at least one first layer made of a first material with a first expansion coefficient, and
at least one second layer made of a second low-stretch material with a second expansion coefficient which is smaller than the first expansion coefficient,
wherein between the first layer and the second layer at least one first bonding layer is formed, which comprises diffusion metal, in particular silver (Ag) and/or a silver alloy and/or gold (Au) and/or a gold alloy and/or copper (Cu) and/or a copper alloy.

The first material preferably comprises metal or consists of metal. In particular the first material comprises copper or the first material is copper or a copper alloy. The second material may be a nickel alloy, in particular Invar (Fe₆₅Ni₃₅) or Invar 36 (Fe₆₄Ni₃₆) or Kovar (Fe₅₄Ni₂₉Co₁₇) and/or tungsten (W) and/or an iron-nickel-cobalt alloy (FeNiCo alloy). Preferably the second material is a nickel alloy, in particular Invar (Fe₆₅Ni₃₅) or Invar 36 (Fe₆₄Ni₃₆) or Kovar (Fe₅₄Ni₂₉Co₁₇) and/or tungsten (W) and/or an iron-nickel-cobalt alloy (FeNiCo alloy).

With an especially preferred embodiment of the invention the second material comprises molybdenum (Mo). With an especially preferred embodiment of the invention the second material is molybdenum (Mo). It is also feasible for the second material to comprise a molybdenum alloy or to be a molybdenum alloy.

The at least one bonding layer may be formed as a boundary layer of the first layer and/or the second layer.

It is possible for the bonding layer to be an independent visible layer. Provided the bonding material is applied merely very thinly during production of the heat-spreading plate according to the invention, the bonding layer in the produced product, i.e. in the produced heat-spreading plate, may be configured as a boundary layer of the first layer and/or the second layer. The bonding material may, for example, be diffused into the first layer and/or the second layer, at least in sections.

Especially preferably the bonding material of the bonding layer is silver or a silver alloy, so that the silver or the silver alloy, if the bonding layer is configured as a boundary layer, is diffused section-wise into the first layer and/or the second layer.

With a further embodiment of the invention the heat-spreading plate comprises at least one third layer, wherein the third layer consists of a/the first material. The third layer is preferably bonded by means of a second bonding layer made of a/the bonding material to the second layer made of the second, low-stretch material. The heat-spreading plate may therefore comprise three layers which are bonded to each other by means of two bonding layers.

With a further embodiment of the invention the heat-spreading plate may comprise at least one fourth layer which is made of a/the second material. The fourth layer is preferably bonded to the third layer made of the first material by means of a third bonding layer made of a/the bonding material. With this embodiment of the invention the heat-spreading plate comprises four layers, which are formed either of the first material or of the second material, wherein these four layers are bonded to each other by at least three bonding layers.

The heat-spreading plate may comprise a symmetrical arrangement of individual layers and bonding layers. Preferably the symmetrical arrangement of individual layers and bonding layer(s) is configured such that a planar heat-spreading plate is formed. A symmetrical arrangement of the individual layers is to be understood such that for a theoretical symmetry axis extending through the heat-spreading plate, a symmetrical arrangement of individual layers and bonding layer(s) with matching materials and layer thicknesses is formed both above and below the symmetry axis. The symmetry axis halves the arrangement of individual layers as regards the overall thickness of the heat-spreading plate, wherein the overall thickness of the heat-spreading plate is formed by totaling the individual layer thicknesses.

In forming a symmetrical arrangement of individual layers and bonding layer(s) it is possible to form a planar heat spreading plate. Individual applications of heat spreading plates may require the surface to which a circuit carrier is mounted to be completely planar. This prevents, for example, the solder from running as well as the circuit carriers from “sliding off” the heat spreading plates to which they are connected by means of the solder. Contacting materials other than solder may also be used.

With an alternative embodiment of the invention it is possible for individual layers and bonding layer(s) to be asymmetrically arranged. The individual layers and bonding layer(s) are, in particular, arranged asymmetrically such that a convexly ore concavely formed heat spreading plate is created. A convexly or concavely formed heat spreading plate may also be called a heat spreading plate with a curvature/a curved side. Preferably the heat spreading plate comprises a controlled convex or concave shape. In other words, the curvature maximum is defined.

An asymmetrical arrangement can be made visible by a theoretically formed symmetry axis. The symmetry axis halves the overall thickness of the arrangement of the individual layers of the heat spreading plate, wherein the overall thickness is defined by totaling the individual layer thicknesses. Preferably the curvature/the convex or concave shape of the heat spreading plate is controlled by configuring and/or forming the second layer and/or the fourth layer from the second material, that is the low-stretch material. Preferably the second layer and/or the at least fourth layer are asymmetrically formed in relation to the overall arrangement of all layers and bonding layer(s), so that a symmetry axis is the aimed-for result of the stretchiness of the produced heat spreading plate.

Depending on the respective application, due to the position and/or formation of the second layer and/or at least the fourth layer from a low-stretch second material after final cooling, a curved heat spreading plate contour can be achieved. To this end the heat spreading plate according to the invention is produced with the aid of a previously mentioned method according to the invention for producing a semiconductor module with a circuit carrier.

With a further embodiment of the invention the second layer and/or at least the fourth layer may be embedded in a layer made of the first material. The layer made of the first material may be the first layer and/or the third layer.

With a further embodiment of the invention the second layer and/or at least the fourth layer are configured frame-like and/or grid-like and/or wire-like. Preferably this configuration of the second layer and/or the fourth layer is effected in combination with embedding the respective layer in a layer made of the first material.

The invention is further based on the idea of proposing a method for producing a semiconductor module, which comprises a heat spreading plate and at least one circuit carrier supporting at least one semiconductor component. Preferably the heat spreading plate is a previously mentioned heat spreading plate according to the invention or a heat spreading plate produced by the previously mentioned method according to the invention.

The method according to the invention for producing a semiconductor module is based on the circuit carrier being connected by means of a contacting layer to the heat spreading plate at a mounting temperature of 150° C.-300° C., wherein the mounting temperature substantially corresponds to the bonding temperature employed during bonding of the layer(s) of the heat spreading plate to each other. In other words the mounting temperature, during connecting the circuit carrier to the heat spreading plate substantially corresponds to the bonding temperature effective during production of the heat spreading plate.

The mounting temperature may correspond exactly to the bonding temperature. Preferably the mounting temperature does not deviate from the bonding temperature by more than max. 20%, in particular max. 15%, in particular max. 10%, in particular max. 5%. Calculation of the percentage deviation of the mounting temperature from the bonding temperature is effected on the basis of a calculation of the difference between the mounting temperature in Kelvin and the bonding temperature in Kelvin.

The mounting temperature may be 200° C.-280° C., in particular 220° C.-270° C., in particular 240° C.-260° C., in particular 250° C.

The circuit carrier is preferably mounted on/connected to the surface of the heat spreading plate, wherein the surface is formed by a layer, in particular the first layer or the third layer, which consists of a first material. The surface may also be called the topmost side of the heat spreading plate.

The contacting layer is for example a sintering paste. It is also possible for the contacting layer to be an adhesive layer or a solder layer.

With one embodiment of the invention the bonding of the layers of the heat spreading plate and the connection of the circuit carrier to the heat spreading plate may be carried out simultaneously. In this embodiment all layers, bonding layer(s) as well as the circuit carrier to be connected are arranged on top of each other and, for example, simultaneously connected to each other by means of a low-temperature sintering process.

By combining the method according to the invention for producing a heat spreading plate with the method according to the invention for producing a semiconductor module it is possible to produce a heat spreading plate with asymmetric arrangement of the layers and bonding layer(s) in such a way that a defined convex or concave deformation of the heat spreading plate, in other words a defined curvature maximum, is created. The individual layers and connecting layer(s) are asymmetrically arranged in relation to each other. The asymmetry can be controlled by the number of layers and/or the layer thicknesses.

The asymmetric arrangement of layers and bonding layer(s) is bonded together at a bonding temperature which essentially corresponds to the mounting temperature of the heat spreading plate with the circuit carrier.

Next connecting the substrate plate to the heat spreading plate is carried out. This revealed that the concave or convex deformation diminishes, when the produced asymmetrical heat spreading plate is reheated, and, following connection of the heat spreading pate to the substrate plate, assumes a temperature-stable final shape in a new stress equilibrium appropriate to the requirement. The temperature-stable final shape may be the defined curvature maximum. A defined curvature maximum is for example 100 μm.

Furthermore the invention is based on the idea of proposing a semiconductor module, wherein the semiconductor module is preferably produced by an above-mentioned method according to the invention. The semiconductor module comprises a heat spreading plate and at least one circuit carrier supporting at least one semiconductor component. The heat spreading plate is preferably a heat spreading plate according to the invention or a heat spreading plate produced by means of the above-mentioned method according to the invention.

The circuit carrier is preferably configured as a DCB (direct copper bonding) substrate. In particular the circuit carrier is configured as a substrate plate made of aluminium oxide (Al₂O₃) and/or aluminium nitride (AIN) and/or silicon nitride (Si₃N₄) and/or zirconia toughened alumina (ZTA). Circuit carriers of this kind have a comparatively small expansion coefficient.

With a further embodiment of the invention the heat spreading plate of the semiconductor module may be connected to a cooler, wherein a heat-conducting paste is preferably formed between the heat spreading plate and the cooler. Mounting the heat spreading plate on a cooler allows intensive and necessary cooling of the power loss of the semiconductor module via the heat spreading plate to the cooler to the environment. With this arrangement it is important that the heat spreading plate, if possible without air gaps or air inclusions, is form-locked to the surface, in particular a mounting plate, of the cooler. Preferably a heat-conducting paste, in particular a plastic heat-conducting paste, is therefore formed between the heat spreading plate and the surface of the cooler/the mounting plate of the cooler. The heat-conducting paste is applied as thinly as possible and free from air inclusions between the heat spreading plate and the surface/the mounting plate of the cooler.

Preferably the curvature of the heat spreading plate is only small. With the aid of the heat spreading plate according to the invention/with the aid of the above-mentioned method a heat spreading plate can be produced which has a small or exactly defined curvature.

The heat spreading plate is preferably mounted with its curved side on the mounting plate/surface of the cooler. The heat spreading plate with the circuit carrier mounted on it can for example be pressed onto or against the cooler by means of screws. Preferably pressing is carried out under slowly increasing tension and at selected pressure positions. The concave or convex shaping or, in other words, the curved shaping of the heat spreading plate initially causes a maximum contact pressure to be applied to the centre of the cooler, wherein as the mounting pressure rises, the heat-conducting paste is squeezed slowly from inside to outside. Preferably this causes a gap between the heat spreading plate and the surface of the cooler/the mounting plate of the cooler to be filled with heat-conducting paste. Surplus heat-conducting paste can be removed using this mounting procedure. Thus damaging accumulation of heat-conducting paste between the heat spreading plate and the surface of the cooler/the mounting plate of the cooler is avoided.

In this way a thermally advantageous form-lock and simultaneously releasable connection is produced between the heat spreading plate and the cooler.

The invention will now be explained in further detail with reference to the attached schematic drawings by way of exemplary embodiments, in which

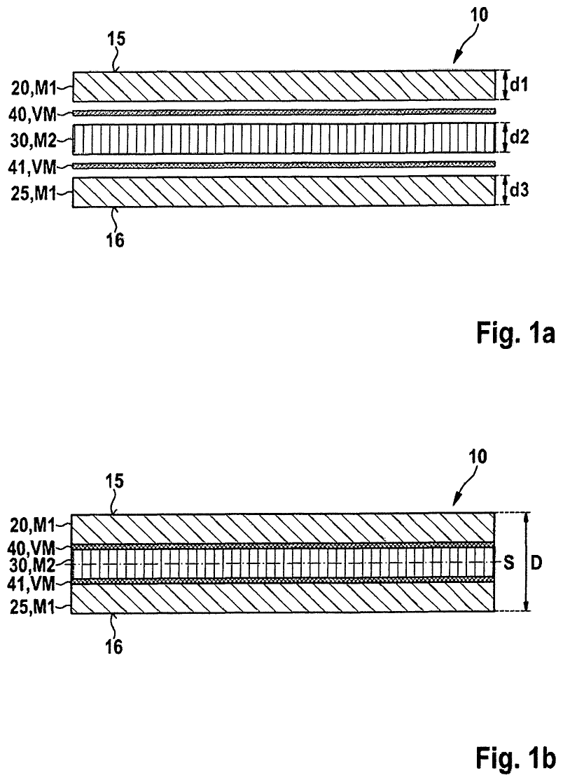

FIG. 1a shows the arrangement of individual layers of a heat spreading plate in a first embodiment;

FIG. 1b shows the heat spreading plate of FIG. 1a in a bonded state;

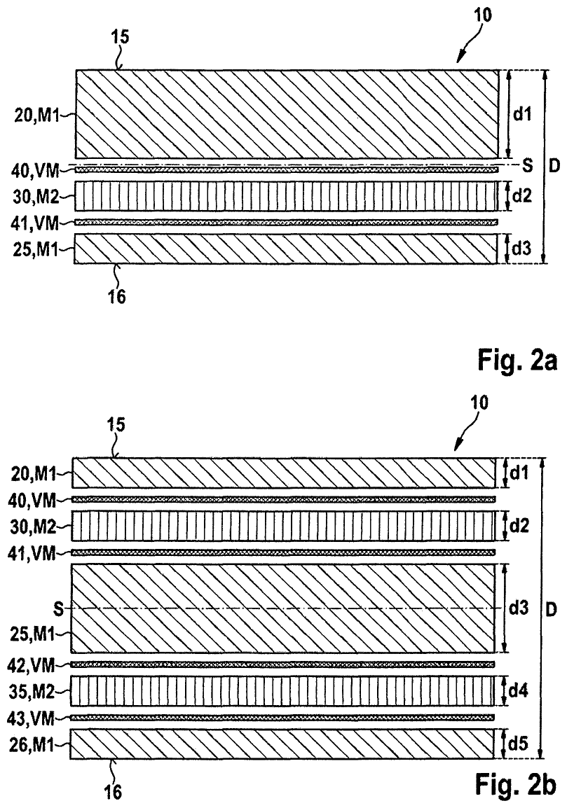

FIG. 2a shows the arrangement of individual layers of a heat spreading plate according to the invention in a second embodiment;

FIG. 2b shows the arrangement of individual layers of a heat spreading plat according to the invention in a third embodiment;

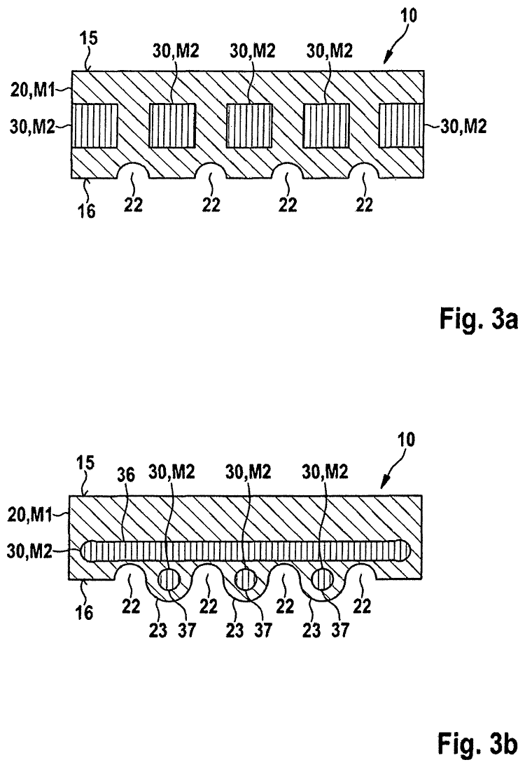

FIGS. 3a and 3b show further embodiments of heat spreading plates according to the invention;

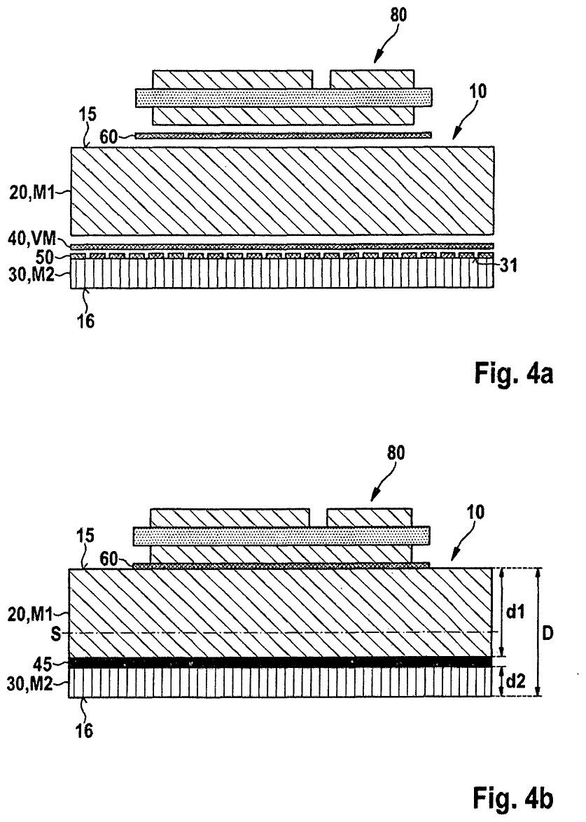

FIGS. 4a and 4b show the arrangement of individual layers of a heat spreading plate according to the invention with circuit carrier in a first embodiment in an unconnected and in a connected state;

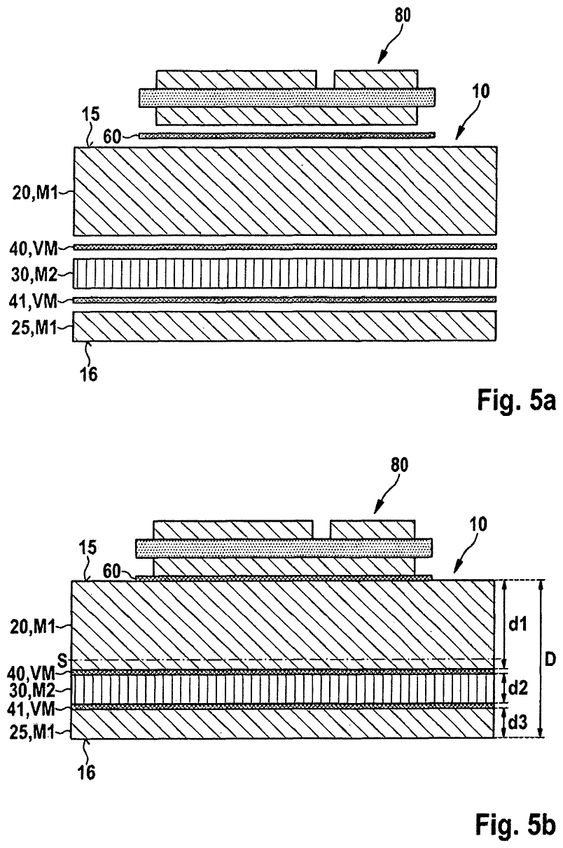

FIGS. 5a and 5b show the arrangement of individual layers of a heat spreading plate according to the invention with circuit carrier in a further embodiment in an unconnected and in a connected state;

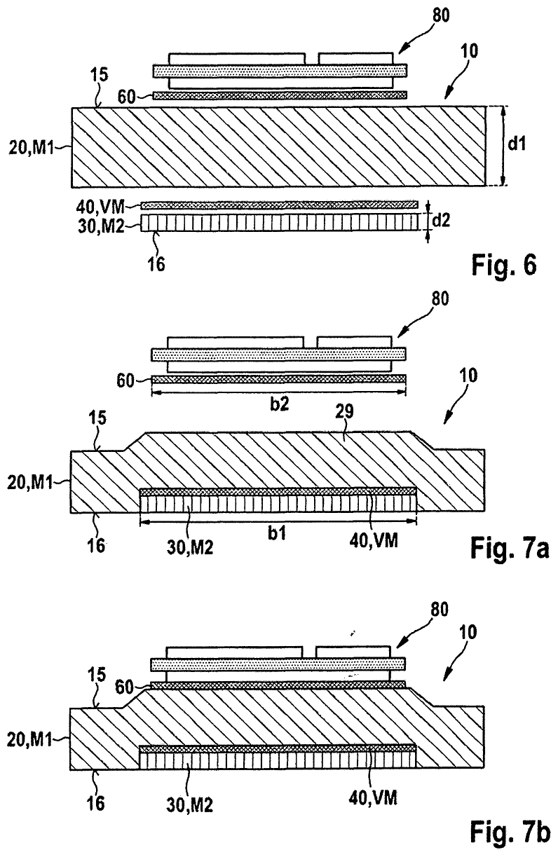

FIG. 6 shows the arrangement of individual layers of a heat spreading plate according to the invention with circuit carrier in a further embodiment;

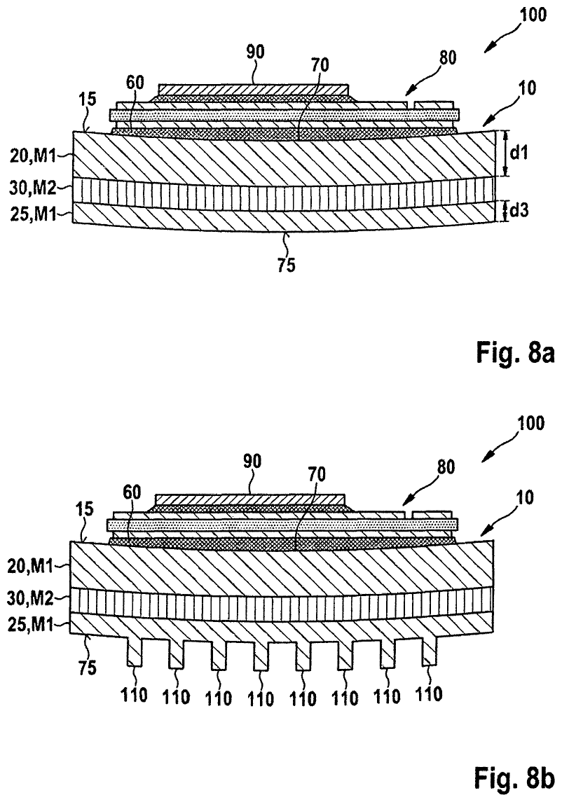

FIGS. 7a and 7b show the arrangement of individual layers of a heat spreading plate according to the invention with circuit carrier in a further embodiment in an unconnected and in a connected state;

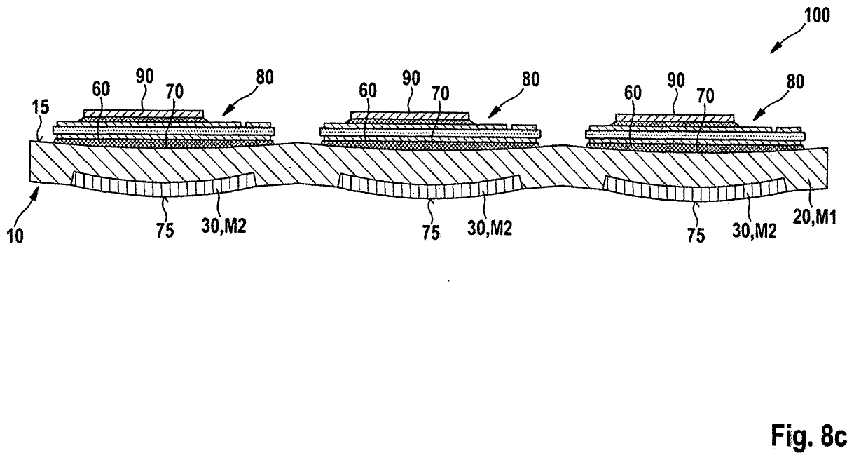

FIGS. 8a-8c show the convex formation of heat spreading plates and circuit carriers arranged thereon in various embodiments; and

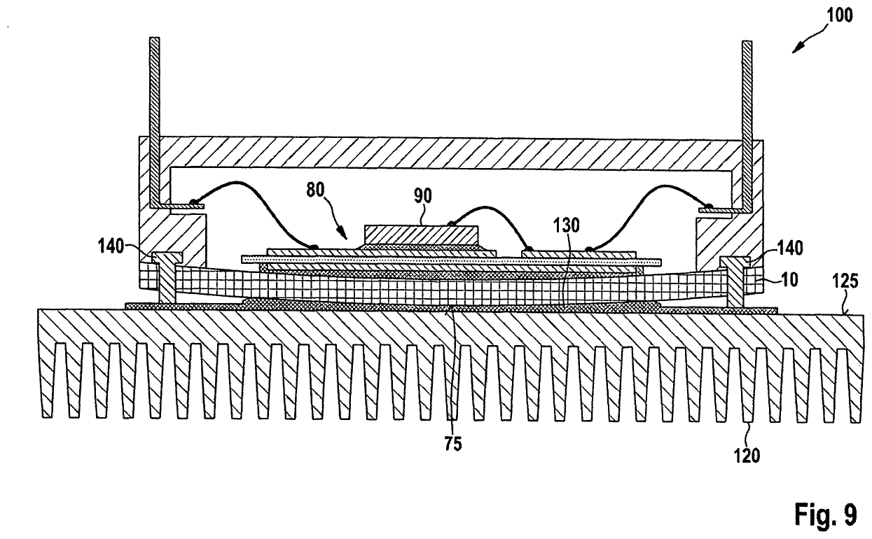

FIG. 9 shows a semiconductor module connected to a cooler.

In the following identical and functionally identical parts are marked with identical reference symbols.

FIG. 1a shows the individual layers of a conventional heat spreading plate 10 (see FIG. 1b). Accordingly the heat spreading plate to be produced comprises a first layer 20 made of a first material M1, a second layer 30 made of a second material M2 and a third layer 25 also made of the first material M1. The material M1 is preferably a metal, in particular copper or a copper alloy. Material M2 on the other hand is a low-stretch material with a second expansion coefficient which is smaller than the first expansion coefficient of the first material M1. The second material M2 may be a nickel alloy, in particular Invar or Invar 36 or Kovar and/or tungsten and/or an iron-nickel-cobalt alloy. In the present embodiment material M2 is molybdenum.

A first bonding layer 40 from a bonding material VM is provided between the first layer 20 and the second layer 30. A second bonding layer 41 from a bonding material VM is provided between the second layer 30 and the third layer 25. The bonding material VM of the bonding layers 40 and 41 creates a bond between the layers 20, 25 and 30, with this bond withstanding temperatures above a bonding temperature. Preferably the bonding layer comprises a diffusion metal, in particular silver and/or a silver alloy and/or gold and/or a gold alloy and/or copper and/or a copper alloy.

Preferably the bonding layer is formed as a sintering layer, in particular a sintering paste. This sintering paste, which preferably comprises one of the named diffusion metals, may for example be applied by means of a printing process.

Preferably the layers 20, 25 and 30 are bonded to each other by a low-temperature method at a bonding temperature of 150° C.-300° C. Especially preferably the bonding temperature is 250° C. The bonding temperature for bonding the layers 20, 25 and 30 with the aid of the bonding layers 40 and 41 substantially corresponds to the mounting temperature during connecting the produced heat spreading plate 10 to a circuit carrier to be mounted.

FIG. 1b shows the produced heat spreading plate 10. The bonding layers 40 and 41 can be recognised. It is possible that bonding layers 40 and 41 are designed as boundary layers of the first layer 20, the third layer 25 and the second layer 30.

Bonding of the first layer 20 to the second layer 30 and the third layer 25 is preferably effected by means of the application of pressure, in particular at a pressure of 5 MPS-30 MPa, in particular 10 MPa-28 MPa, in particular 25 MPa.

As can be recognised from FIGS. 1a and 1b, the layer thicknesses d1 of the first layer 20, d2 of the second layer 30 and d3 of the third layer 25 are identical. With the aid of the symmetry axis S plotted in FIG. 1b it can be seen that the heat spreading plate 10 is built-up symmetrically from individual layers 20, 25 and 30 as well as the bonding layers 40 and 41. The symmetry axis S halves the overall thickness D of the heat spreading plate 10. The overall thickness D is formed by totaling the layer thicknesses d1, d2 and d3. Above and below the symmetry axis S a symmetrical structure of the heat spreading plate 10 is obvious. Using such a heat spreading plate permits a planar structure/a planar shaping of the heat spreading plate 10.

FIG. 2a by contrast shows an asymmetrical arrangement of individual layers 20, 25 and 30 and bonding layers 40 and 41. With regard to materials and bonding options of individual layers 20, 25 and 30 reference should be made to the above explanations in conjunction with FIGS. 1a and 1b.

It can be seen that the layer thickness d1 of the first layer 20 is larger than the layer thickness d2 of the second layer 30 as well as the layer thickness d3 of the third layer 25. A hinted at symmetry axis S which halves the overall thickness D of the heat spreading plate 10, shows that the heat spreading plate 10 to be formed, comprises an asymmetrical arrangement of individual layers above and below the symmetry axis S. Preferably the layer thickness d1 is between 0.2 mm and 3.0 mm, whereas the layer thickness d2 is between 0.1 mm and 2.0 mm. The thickness of the first bonding layer 40 and/or the second bonding layer 41 is for example between 1 μm and 50 μm. The layer thickness d3 may be between 0.2 mm and 3.0 mm.

FIG. 2b by contrast shows a symmetrical structure/a symmetrical arrangement of individual layers 20, 25, 26, 30, 35 and bonding layers 40, 41, 42, 43. It can be recognised that the heat spreading plate 10 to be produced may also comprise two layers made of the second low-stretch material M2. These are the second layer 30 and the fourth layer 35. Above and below the second layer 30 and the fourth layer 35 a layer from a first material M1 is respectively provided, which is, respectively, the first layer 20, the third layer 25 as well as the fifth layer 26. The individual layers which consist of the first material M1, i.e. layers 20, 25 and 26, are bonded to the layers consisting of the second low-stretch material M2, i.e. the second layer 30 and the fourth layer 35, by means of bonding layers 40, 41, 42 and 43. The bonding layers 40, 41, 42 and 43 preferably comprise the same bonding material VM. Preferably this is a sintering material, in particular a sintering paste, which for example comprises silver and/or silver oxide and/or silver carbonate.

The symmetry axis S hinted at shows that the embodiment shown in FIG. 2b depicts a symmetrical arrangement of the layers 20, 25, 26, 30, 35 and the bonding layers 40 to 43. With the aid of a heat spreading plate 10, as shown in FIG. 2b, it is possible to achieve a reduction in stretch of the marginal layers 20 and 26 which preferably consist of copper. This is done with the aid of two spaced-apart layers 20 and 35, which consist of a low-stretch material, in particular molybdenum.

FIG. 3a shows a further embodiment of the heat spreading plate 10. Here a second layer 30 is configured as a grid. The grid would be visible when looking from the top onto a first side 15 of the first layer 20. The second layer 30 is embedded into in the first layer 20 made of the first material M1. Semi-circular recesses 22 are formed on the side 16 opposite the first side 15 of the heat spreading plate 10.

According to the embodiment depicted in FIG. 3b of the heat spreading plate 10 it is again provided that the second layer 30 is embedded in the first layer 20. On the side 16 opposite the first side 15 of the heat spreading plate 10 both recesses 22 and bulges 23 are formed. The second layer 30 is formed from an upper portion 36 and a lower portion 37. The lower portion 37 is formed like a wire. The cross-sections of the wires can be recognised. The wires of the lower portion 37 are positioned in the bulges 23. The upper portion 36 by contrast is shaped like a plate, but comprises a smaller width than the first layer 20.

In FIG. 4a the individual layers/components of a semiconductor module to be produced are depicted. The heat spreading plate 10 is thus formed from a first layer 20 of a first material M1 and a second layer 30 from a second material M2. A bonding layer 40 is formed between the first layer 20 and a second layer 30. This bonding layer is preferably a sintering layer which comprises a bonding material VM, i.e. silver.

On the first side 31 of the second layer 30 a bond-enhancing layer 50 is applied. The first side 31 of the second layer 30 is the side of the second layer 30 facing the first layer 20. The bond-enhancing layer 50 is preferably applied by electroplating onto the second layer 30. The bond-enhancing layer 50 is for example a nickel-silver layer. With the aid of the bond-enhancing layer 50 the adhesion between the second layer 30 and the bonding layer 40 can be improved. In the bonded state (see FIG. 4b) a combined bonding layer 45 is created. The bonding layer 40 and the bond-enhancing layer 50 are pressed together using a low-temperature sintering process so that the combined bonding layer 45 is formed.

The hinted-at symmetry axis S in FIG. 4b helps to recognise that the heat spreading plate 10 has an asymmetrical structure. With regard to the symmetry axis S the preceding explanations apply. The asymmetrical structure is achieved by different layer thicknesses of the first layer 20 and the second layer 30. The layer thickness d1 of the first layer 20 is larger than the layer thickness d2 of the second layer 30.

The circuit carrier 80 is for example a so-called DCB substrate. This may be configured as a substrate plate made of aluminium oxide and/or silicon nitride and/or zirconia-toughened alumina.

A contacting layer 60 is provided for connecting the circuit carrier 80 to the heat spreading plate 10. This contacting layer 60 may for example be a sintering paste. It is also feasible for the contacting layer 60 to be an adhesive layer or a solder layer. The circuit carrier 80 is attached by means of the contacting layer 60 to the side 15 of the heat spreading plate 10 which faces the circuit carrier 80. The surface 15 of the heat spreading plate 10 to be connected to the circuit carrier 80 is the first side 15 of the first layer 20, wherein the first side 15 of the first layer 20 is configured so as to face away from the second layer 30.

Connecting the circuit carrier 80 to the heat spreading plate 10 is carried out by applying a mounting temperature of 150° C.-300° C. to the arrangement, wherein the mounting temperature substantially corresponds to the bonding temperature when bonding the layers 20 and 30 of the heat spreading plate 10. It is possible that both the layers 20 and 30 as well as the circuit carrier 80 are connected together in a single step, i.e. simultaneously.

The embodiment of the invention depicted in FIGS. 4a and 4b represents the smallest possible thermal stack with regard to a heat spreading plate 10, which can be connected to a circuit carrier 80.

FIGS. 5a and 5b also show an asymmetrical structure of a heat spreading plate 10. In contrast to the embodiments of FIGS. 4a and 4b the heat spreading plate 10 here consists of a first layer 20, a second layer 30 and a third layer 25. The first layer 20 and the third layer 25 comprise a first material M1. The material is preferably copper. Between these two layers 20 and 25 which have different layer thicknesses d1 and d3, a second layer 30 from a second material M2 is formed. The second material M2 consists of a low-stretch material/the expansion coefficient of the second material M2 is smaller than the expansion coefficient of the first material M1. The asymmetrical heat spreading plate 10 again has a circuit carrier 80 formed on it and therefore can, together with a semiconductor component 90 (not shown), form a semiconductor module 100.

The embodiment of a semiconductor module depicted in FIG. 6 is also based on an asymmetric heat spreading plate 10. A first layer 20 from a first material M1, such as copper, is bonded to a second layer 30 from a second low-stretch material M2. To this end a bonding layer 40 is provided between the two layers 20 and 30. The layer thickness d1 of the first layer 20 is six times that of the layer thickness d2 of the second layer 30. Again, a circuit carrier 80 can be attached on the first side 15 of the first layer 20 with the aid of a contacting layer 60.

The second layer 30 also has a smaller width than the first layer 20. The width of the second layer 30 corresponds approximately to the width of the contacting layer 60.

In the embodiment shown in FIGS. 7a and 7b a further arrangement consisting of a heat spreading plate 10 and a circuit carrier 80 is depicted. FIG. 7a shows the two components in an unconnected state.

The heat spreading plate 10 comprises a first layer 20 as well as a second layer 30. The second layer 30 is embedded in the first layer 20 which consists of the first material M1. The geometrically smaller layer 30 is thus placed into a hollow of the first layer 20 and connected by means of a bonding layer 40. The width b1 of the second layer 30 substantially corresponds to the width b2 of the contacting layer 60. The circuit carrier 80 is arranged above the second layer 30 such that the circuit carrier 80, in particular the contacting layer 60, is configured congruently with the second layer 30.

The heat spreading plate 10 also comprises a raised plateau 29. The circuit carrier 80 can be attached to the topmost side 15 on this plateau 29. The raised plateau 29 may serve as a mounting aid. Moreover this plateau 29 contributes to an asymmetrical arrangement of the individual layers of the heat spreading plate 10. The plateau may for example be produced by pressing the layers 20 and 30 shown in FIG. 6 together.

FIG. 8a shows a semiconductor module 100, wherein the heat spreading plate 10 has a concave shape. The concave shape of the heat spreading plate 10 is the result of the asymmetrically structure of the heat spreading plate 10. The layer thickness d3 of the third layer 25 is smaller than the layer thickness d1 of the first layer 20, so that the heat spreading plate 10 is generally bent in direction of the third layer 25. A circuit carrier 80, which has a semiconductor component 90 attached to it, is connected to the first side 15 of the first layer of the heat spreading plate 10, i.e. the topmost side 15 of the heat spreading plate 10. The circuit carrier 80 is connected to the heat spreading plate 10 such that the indentation 70 created because of the concave shape of the heat spreading plate 10 marks the central position of the circuit carrier 80.

FIG. 8b shows a further semiconductor module 100. The heat spreading plate 10 in this embodiment comprises cooling fins 110. In other respects the structure of the semiconductor module 100 of FIG. 8b is the same as the structure of the embodiment shown in FIG. 8a.

FIG. 8c shows that a heat spreading plate 10 may comprise a number of concave hollows thereby forming three indentations 70 in the example shown, wherein the three circuit carriers 80 are each arranged centrally to the indentation 70 on the first side 15 of the first layer 20. The concave hollows/curved sides 75 of the heat spreading plate 10 are formed in that three portions of second layers 30 are embedded in the first layer 20 consisting of a first material M1. The second layers 30 are arranged such that the curved sides/the indentations 70 are formed above/below the position of the respectively second layer 30.

It would be possible to split the arrangement of FIG. 8c up, so that three mutually independent semiconductor modules 100 are formed.

FIG. 9 shows a semiconductor module 100, which comprises a concavely shaped heat spreading plate 10, a circuit carrier 80, a cooler 120 as well as a semiconductor component 90 placed on and connected to the circuit carrier 80. A heat-conducting paste 130 is applied between the heat spreading plate 10 and the cooler 120. The heat-conducting paste 130 is preferably a plastic paste, which is applied as thinly as possible and free from air inclusions between the heat spreading plate 10 and the cooler 120. The curved side 75/the side of the heat spreading plate 10 opposite the indentation 70 is mounted onto the surface 125 of the cooler 120.

The heat spreading plate 10 is pressed onto the surface 125 of the cooler 120 with the aid of screws 140 which act as a clamping device. As the mounting pressure rises, the heat-conducting paste 130 is squeezed from inside to outside and in this way fills the gap between the heat spreading plate 10 and the surface 125 of the cooler 120.

FIG. 9 merely shows a partially mounted state. In the fully mounted state the heat spreading plate 10 is preferably fully supported against the surface 125 of the cooler 120. A rough surface 125 or a contour error of the heat spreading plate 10 and the cooler 120 are compensated for by the heat-conducting paste 130. The cooler 120 shown is a so-called air cooler.

1-20. (canceled)

21. A method for producing a heat spreading plate for a circuit carrier, comprising:
bonding at least one first layer made of a first material having a first coefficient of expansion with at least one second layer made of a second low-stretch material having a second coefficient of expansion smaller than the first coefficient of expansion to each other;
wherein the bonding of the at least one first and second layers is at a bonding temperature of 150° C.-300° C. by means of a low-temperature sintering process;
wherein at least one bonding layer from a bonding material is formed between the first layer and the second layer and the bonding temperature substantially corresponds to a mounting temperature at which the produced heat spreading plate is connected to at least one circuit carrier.

22. The method of claim 21, wherein the bonding temperature is between 240°-260° C.

23. The method of claim 21, wherein the bonding material of the bonding layer produces a bond that withstands temperatures above the bonding temperature, and comprises a diffusion metal comprising one of a group comprising silver (Ag), a silver alloy, gold (Au), a gold alloy, copper (Cu), and a copper alloy.

24. The method of claim 21, wherein the first material comprises a metal comprising one of a group comprising copper (Cu), a copper alloy, and the second material comprises one of a group comprising a nickel alloy, Invar (Fe₆₅Ni₃₅), Invar 36 (Fe₆₄Ni₃₆), Kovar (Fe₅₄Ni₂₉Co₁₇), tungsten (W), an iron-nickel-cobalt alloy (FeNiCo alloy), and molybdenum (Mo).

25. The method of claim 21, wherein bonding the at least first layer to the at least second layer and the at least first bonding layer is effected by means of pressure application at a pressure of between 10 MPa-28 MPa.

26. A heat spreading plate for a circuit carrier, comprising:
at least one first layer made of a first material having a first coefficient of expansion bonded to at least one second layer made of a second low-stretch material having a second coefficient of expansion that is smaller than the first coefficient of expansion;
wherein at least one first bonding layer is formed between the first layer and the second layer; and
wherein the at least one first bonding layer comprises a diffusion metal comprising one of a group comprising silver (Ag), a silver alloy, gold (Au), a gold alloy, copper (Cu), and a copper alloy.

27. The heat spreading plate of claim 26, wherein the at least one first bonding layer is configured as a boundary layer of the first layer and/or the second layer.

28. The heat spreading plate of claim 26, wherein the first material comprises one of a group comprising copper (Cu) and a copper alloy, and the second material comprises one of a group comprising a nickel alloy, Invar (Fe₆₅Ni₃₅), Invar 36 (Fe₆₄Ni₃₆), Kovar (Fe₅₄Ni₂₉Co₁₇), tungsten (W), an iron-nickel-cobalt alloy (FeNiCo alloy), and molybdenum (Mo).

29. The heat spreading plate of claim 26, wherein at least one third layer made of the first material, which is bonded by means of a second bonding layer from the bonding material to the second layer made of the second low-stretch material.

30. The heat spreading plate of claim 29, wherein at least one fourth layer from the second material, which is bonded by means of a third bonding layer made of the bonding material to the third layer made of the first material.

31. The heat spreading plate of claim 30, wherein the at least one first through fourth layers and the bonding layers are in a symmetrical arrangement such that a planar heat spreading plate is formed.

32. The heat spreading plate of claim 30, wherein the at least one first through fourth layers and the bonding layers are in an asymmetrical arrangement, such that a convexly or concavely shaped heat spreading plate is formed.

33. The heat spreading plate of claim 30, wherein the second layer or the fourth layer is embedded in a layer from the first material.

34. The heat spreading plate of claim 30, wherein the second layer or the fourth layer is shaped one of frame-like, grid-like, and wire-like.

35. A method for producing a semiconductor module, comprising:
forming a heat spreading plate by bonding at least one first layer made of a first material having a first coefficient of expansion with at least one second layer made of a second low-stretch material having a second coefficient of expansion smaller than the first coefficient of expansion to each other;
wherein the bonding of the at least one first and second layers is at a bonding temperature of 150° C.-300° C. by means of a low-temperature sintering process;
wherein at least one bonding layer from a bonding material is formed between the first layer and the second layer and the bonding temperature substantially corresponds to a mounting temperature during connection of the produced heat spreading plate to at least one circuit carrier;
wherein the at least one circuit carrier supports at least one semiconductor component;
wherein the circuit carrier is connected by means of a contacting layer to the heat spreading plate at a mounting temperature of 150° C.-300° C.; and
wherein the mounting temperature essentially corresponds to the bonding temperature at which the layers of the heat spreading plate are bonded together.

36. The method of claim 35, wherein the bonding of the layers of the heat spreading plate and the bonding of the circuit carrier to the heat spreading plate is carried out simultaneously.

37. The method of claim 35, wherein the mounting temperature is between 240° C.-260° C.

38. A semiconductor module, comprising
a heat spreading plate, comprising:
at least one first layer made of a first material having a first coefficient of expansion bonded to at least one second layer made of a second low-stretch material having a second coefficient of expansion that is smaller than the first coefficient of expansion;
wherein at least one first bonding layer is formed between the first layer and the second layer; and
wherein the at least one first bonding layer comprises a diffusion metal comprising one of a group comprising silver (Ag), a silver alloy, gold (Au), a gold alloy, copper (Cu), and a copper alloy; and
at least one circuit carrier supporting at least one semiconductor component.

39. The semiconductor module of claim 38, wherein the circuit carrier is configured as a DCB substrate from at least one of a group comprising aluminium oxide (Al₂O₃), aluminium nitride (AlN), silicon nitride (Si₃N₄), and zirconia toughened alumina (ZTA).

40. The semiconductor module of claim 38, wherein the heat spreading plate is connected to a cooler, and wherein a heat-conducting paste is formed between the heat spreading plate and the cooler.
